(19) United States
(12) Patent Application Publication
(10) Pub. No.: US 2026/0173901 A1
(43) Pub. Date: Jun. 18, 2026

(54) SEMICONDUCTOR DEVICE AND METHOD FOR FABRICATING A SEMICONDUCTOR DEVICE

(71) Applicant: Infineon Technologies Austria AG, Villach (AT)

(72) Inventors: Stefan Pelties, Regensburg (DE); Alexander Heinrich, Bad Abbach (DE); Edward Fürgut, Dasing (DE)

(21) Appl. No.: 19/421,363

(22) Filed: Dec. 16, 2025

(30) Foreign Application Priority Data
Dec. 17, 2024 (DE) 102024138432.8

(51) Int. Cl. H10W 70/40; H10W 70/04; H10W 72/00; H10W 90/00

(52) U.S. Cl. CPC H10W 70/479; H10W 70/047; H10W 70/457; H10W 70/458; H10W 72/07336; H10W 90/736

(57) ABSTRACT

A semiconductor package includes: a substrate having an insulation layer with a first upper main face and a second lower main face opposite to the first upper main face; a leadframe having a first upper main face and a second lower main face opposite to the first main face; a semiconductor transistor die arranged on the first main face of the leadframe; a joint layer coupling the second lower main face of the leadframe to the first upper main face of the ceramic insulation layer, the joint layer having a melting point entirely or in parts of greater than 260° C.; and an encapsulation covering an inner portion of the leadframe, the semiconductor transistor die, and the ceramic insulation layer.

### TECHNICAL FIELD

This disclosure relates in general to semiconductor devices as well as to methods for fabricating semiconductor devices.

### BACKGROUND

Semiconductor devices, in particular power semiconductor devices, may be required to fulfil stringent electrical performance requirements. For example, such semiconductor devices may be required to carry strong electrical currents, to operate at high voltages, to have low R_{DS(on)}, etc. These requirements also apply to joints electrically coupling different parts of a semiconductor device to one another. In particular solder joints often do not necessarily fulfil these requirements in every application. Furthermore, another major problem is the efficient dissipation of excessive heat generated by the semiconductor power transistor to which the electrical interconnection layers must also make an important contribution.

Improved semiconductor devices and improved methods for fabricating semiconductor devices may help with solving these and other problems.

For these and other reasons there is a need for the present disclosure.

### SUMMARY

A first aspect of the present disclosure pertains to a semiconductor package comprising a substrate comprising an insulation layer, the insulation layer comprising a first upper main face and a second lower main face opposite to the first upper main face, a leadframe comprising a first upper main face and a second lower main face opposite to the first main face, a semiconductor transistor die arranged on the first main face of the leadframe, a joint layer coupling the second lower main face of the leadframe to the first upper main face of the ceramic insulation layer, wherein the joint layer comprises a melting point entirely or in parts of greater than 260° C., and an encapsulation covering an inner portion of the leadframe, the semiconductor transistor die, and the ceramic insulation layer.

The high melting point of greater than 260° C. of the joint layer according to the semiconductor package according to the first aspect will allow the customer to apply a heatsink with high temperatures, still below 260° C. Generally, the joint layer may be a bond line having a thickness (BLT) in a range of more than 20 μm to 200 μm. Particularly, the BLT may be in a range of more than 40 μm to 200 μm. In this range and its sub-ranges solder-systems based on Sn comprising high melting core materials are applied. BLTs in a range of 1 μm to 50 μm are however also envisaged. In this rage a sub-range of 10 μm-30 μm has turned out to be advantageous.

A second aspect of the present disclosure pertains to a method for fabricating a semiconductor package, the method comprising providing a substrate comprising an insulation layer, the insulation layer comprising a first upper main face and a second lower main face opposite to the first upper main face, providing a leadframe comprising a first upper main face and a second lower main face opposite to the first main face, disposing a semiconductor transistor die on the first main face of the leadframe, applying a joint layer on one or both of the second lower main face of the leadframe or the first upper main face of the insulation layer, wherein the joint layer is formed by diffusion soldering or diffusion sintering from at least one source material with at least one first transition temperature, wherein after the forming, the joint layer has a second transition temperature higher than the first transition temperature, connecting the leadframe to the substrate by performing a melting and subsequent reflow process, and applying an encapsulation covering an inner portion of the leadframe, the semiconductor transistor die, and the insulation layer.

According to an embodiment of the semiconductor package of the first aspect the joint layer comprises a material of one or more of the group consisting of a Pb free material, an SnSb material, an NiSn material, an Sn material, a Cu material, an Ag material, an Ag glue material, or a hybrid sinter paste. Soldering systems based on SnSb materials have turned out to be advantageous, but systems based on Cu materials, that is Cu alloys may also be used.

In particular, the joint layer of the semiconductor package of the first aspect may comprise a diffusion active layer system or a diffusion active particulate system, wherein the diffusion active layer system and/or the diffusion active particulate system comprises sintered particles, metals or intermetallic compounds. In the context of this disclosure the term “diffusion active layer systems” may refer to Sn—Cu—Sn layer systems, but also to solder paste systems with high melting points.

The joint layer may in particular comprise a sintering paste, a sintering layer or a sintering sheet.

According to the method of the second aspect the second transition temperature can be higher than 260° C.

According to an embodiment of the semiconductor package of the first aspect the Pb-free material of the joint layer as one of the above described embodiments does not preclude the possibility that trace elements of lead may be present, which may inevitably occur in the production process.

According to an embodiment of the semiconductor package of the first aspect the joint layer is based on or comprises a metal. In terms of the method according to the second aspect it could be so that the at least one source metal used for fabricating the joint layer comprises a metal.

According to an embodiment of the semiconductor package of the first aspect the joint layer comprises a thickness in a range from 40 μm to 200 μm, in particular from 100 μm to 200 μm, in particular from 50 μm to 150 μm; or wherein the joint layer comprises a thickness in a range from 1 μm to 50 μm, particularly from 10 μm to 30 μm.

According to an embodiment of the semiconductor package of the first aspect the joint layer comprises a material with a thermal conductivity of more than 15 W/mK.

According to an embodiment of the semiconductor package of the first aspect the joint layer comprises a material of one or more of the group consisting of a Pb free material, a CuSn material, a transient liquid phase soldering material, an SnSb material, an NiSn material, an Sn material, an Ag material, an Ag glue material, a Cu material, a Cu glue material, or a hybrid sinter paste.

According to an embodiment of the semiconductor package of the first aspect the ceramic insulation layer is a central layer of the substrate, wherein the substrate is one of a direct copper bond (DCB), an active metal braze (AMB), or an insulated metal substrate (IMS). Further, the ceramic insulation layer may be a layer comprising sputtered ceramics or direct plated Cu ceramics. Particularly, the ceramic insulation layer may be a layer comprising a metallization layer, the metallization layer having a thickness in a range of 1 to 50 μm

According to an embodiment of the semiconductor package of the first aspect the substrate comprises a central layer, a first upper metallic layer and a second lower metallic layer. According to an example thereof, the first upper metallic layer comprises a thickness thinner than 2000/1000/800/300/250/125/75/50/20/10 μm or below and even down to 1 μm. The first upper metallic layer can be a sputtered seed layer or an organic seed layer. Particularly, the thickness of the first upper metallization layer may be in a range from 500 μm-10 μm. More particularly, the first upper metallic layer may have a thickness below 300 μm, preferably 127 μm, 20 μm or 10 μm.

A first upper metallization layer having a thickness of 300 μm may be most suitable for Direct Copper Bond Substrates, while a thickness of 127 μm may be most suitable for Active Metal Braze Substrates (AMB). A thickness of 20 μm may be suitable for a Direct Plated Copper Substrate (DPC).

According to an embodiment of the semiconductor package of the first aspect the substrate is comprised of a single insulating layer with a bottom surface being disposed to the outside. At customer's side a heatsink could be applied directly to the bottom surface of the single ceramic layer. The size of the heatsink can be large as compared to the semiconductor package. Otherwise on both sides of the ceramic layer a metallic layer could be applied. On the upper side it may be required for the joint layer but not required on system level, especially for high voltage and AMD TSC. Asymmetrical designs tend to bend, therefore a thinner metallic layer may be applied.

According to an embodiment of the semiconductor package of the first aspect the ceramic insulation layer comprises one or more of the materials out of the group consisting of Al2O3, Si3N4, H—AlN, AlN, and diamond. Instead of a ceramic insulation layer, other insulation layers are conceivable, too. In particular, the insulation layer may be an IMS (Isolated Metal Substrate) or may be made of an organic insulator material. The insulation layer may be a multilayer organic substrate comprising thermally conductive layers, comprising e.g. epoxy, polyimide, silicone, which may be filled with ceramic particles e.g. Al2O3, AlN, BN, diamond, etc.

The semiconductor transistor die can be a wide band gap semiconductor transistor die, in particular a GaN, a SiC, or a gallium oxide Ga2O3 transistor die.

Furthermore the semiconductor transistor die can be configured as a power semiconductor transistor die. A power transistor is a switching device that is rated to accommodate voltages of at least 20 V (volts) and more commonly on the order of 100V, 600 V, 1200V, 2kV, 3.3kV or more and/or is rated to accommodate currents of at least 1 A (amperes) and more commonly on the order of 10 A, 50 A, 100 A, 500 A, 1000 A or even more. The power transistor die can be part of a multi-chip configuration and/or a multi die pad configuration.

The interconnect technologies as described within this disclosure comprise soldering including reflow and vapor phase solder, sintering, in particular Ag and Cu sintering as well as pressure and pressure-less sintering. Furthermore additional thermal interface materials could be used like, for example, phase change materials, thermal grease materials, gap pads, gap fillers, thermal conductive glues, and graphite pads.

The present disclosure provides an optimum solution for both electrically insulating and at the same time efficiently dissipating the excessive heat produced by the semiconductor power transistor die when the semiconductor device is in operation.

An embodiment of the connecting of the leadframe to the substrate according to the method of the second aspect comprises a soldering process, in particular a diffusion soldering process.

An embodiment of the method of the second aspect is furthermore to utilize either diffusion soldering or sintering in the fabrication process of the joint layer, i.e. to fabricate a material that, through sintering or intermetallic compound formation, has a melting point that is higher than that of the starting material.

Further embodiments can be formed according to embodiments of the semiconductor package of the first aspect.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a cross-sectional view of a semiconductor package comprising a direct copper bond as substrate.

FIG. 2 shows a cross-sectional view of a semiconductor package comprising a substrate a single insulating ceramic layer at the bottom of the device.

FIGS. 3A and 3B show cross-sectional representations of semiconductor devices showing different effects of warpage.

FIGS. 4A and 4B show cross-sectional representations of semiconductor devices comprising additional copper blocks within the joint layer.

FIG. 5 shows a cross-sectional representation of a semiconductor device in order to focus on the die attach layer.

FIG. 6 shows a flow diagram of an embodiment of the method according to the second aspect.

### DETAILED DESCRIPTION

In the following detailed description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The semiconductor devices described below may include one or more semiconductor dies. By way of example, one or more power semiconductor dies may be included. Further, one or more logic integrated circuits may be included in the semiconductor devices. The logic integrated circuits may be configured to control the integrated circuits of other semiconductor dies, for example the integrated circuits of power semiconductor dies. The logic integrated circuits may be implemented in logic dies.

The semiconductor dies may have contact pads which allow electrical contact to be made with the integrated circuits included in the semiconductor dies. They may include one or more contact pad metal layers which are applied to the semiconductor material of the semiconductor dies. The contact pad metal layers may be manufactured with any desired geometric shape and any desired material composition. For example, they may comprise or be made of a material selected from the group of Cu, Ni, NiSn, Au, Ag, Pt, Pd, W, or an alloy of one or more of these metals. W (tungsten) could be used especially in the so-called LTTC process (Low Temperature cofired ceramics) by applying temperatures around 500° C. and also in a HTTC (High Temperature cofired ceramics) by applying temperatures around 1000° C. together with “cofired ceramic” substrates and multi-layer ceramic substrates.

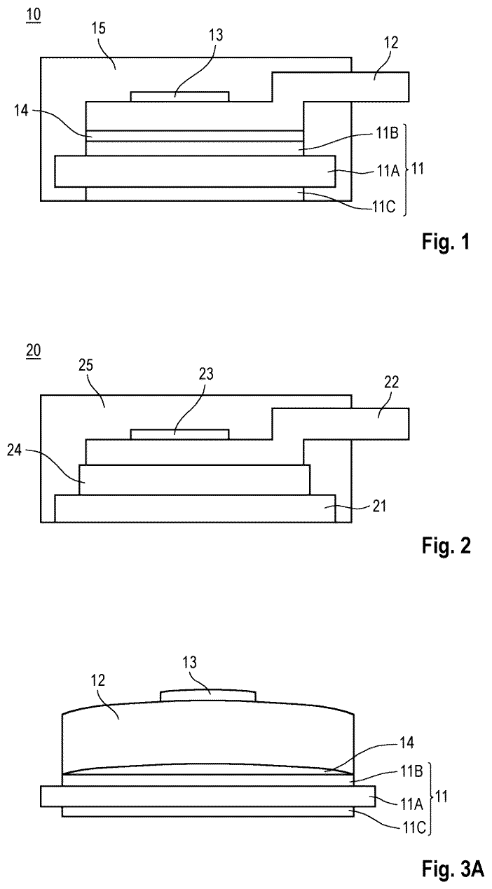

FIG. 1 shows a cross-sectional view of a semiconductor package comprising a direct copper bond substrate.

More specifically, the semiconductor package 10 as shown in FIG. 1 comprises a substrate 11 which may comprise a DCB, AMB or IMS, in any case an insulation layer 11A, which can be an organic insulation layer, or an inorganic insulation layer, in particular a ceramic insulation layer, and even a multi-layer insulation. The insulator layer 11A comprises a first upper main face and a second lower main face opposite to the first upper main face. The package 10 furthermore comprises a leadframe 12 comprising a first upper main face and a second lower main face opposite to the first main face, furthermore a semiconductor transistor die 13 arranged on the first main face of the leadframe 12, furthermore a joint layer 14 coupling the second lower main face of the leadframe 12 to the first upper main face of the ceramic insulation layer 11A, wherein the joint layer 14 comprises a melting point entirely or in parts of greater than 260° C., and an encapsulation 15 covering an inner portion of the leadframe 12, the semiconductor transistor die 13, and the ceramic insulation layer 11 of the substrate 11.

It should be noted that instead of a direct copper bond (DCB) also an active metal braze (AMB) or an insulated metal substrate (IMS) and also the afore-mentioned LTTC or HTTC “cofired ceramic” substrates could be used.

FIG. 2 shows a cross-sectional view of a semiconductor package comprising a substrate a single insulating layer at the bottom of the device.

More specifically, FIG. 2 shows a semiconductor package 20 comprising a substrate 21 comprising a single insulation layer 21, the insulation layer 21 comprising a first upper main face and a second lower main face opposite to the first upper main face, a leadframe 22 comprising a first upper main face and a second lower main face opposite to the first main face, a semiconductor transistor die 23 arranged on the first main face of the leadframe 22, a joint layer 24 coupling the second lower main face of the leadframe 22 to the first upper main face of the insulation layer 21, wherein the joint layer 24 comprises a melting point entirely or in parts of greater than 260° C., and an encapsulation 25 covering an inner portion of the leadframe 22, the semiconductor transistor die 23, and the insulation layer 21.

It should be noted that that the present disclosure can be applied to different types of packages. One of them is shown in FIGS. 1 and 2 and indicates a TO247 package. But also other types of packages are conceivable. There are conceivable, for example, surface mounted devices with top side cooling (SMD TSC), or packages comprising a surface mounting device together with bottom side cooling (SMD BSC), wherein the device could be soldered on a heat sink. Additionally, power modules are conceivable, either single sided or double sided. Further so-called intelligent power modules including a driver die may be considered, either single sided or double sided.

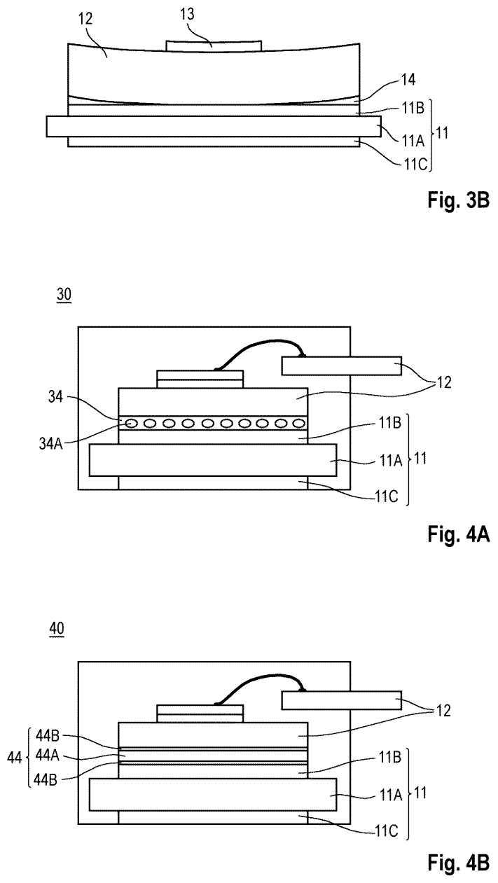

FIGS. 3A and 3B show cross-sectional representations of semiconductor devices showing different effects of warpage.

One can see different outcomes of the process dependant on different material parameters.

The warpage of the lead frame plus semiconductor chip is determined in this case by the ‘die’ or by the different coefficients of thermal expansion (CTE) of the various materials (SiC, Cu). At room temperature, a “sad face” such as shown in FIG. 3A should always result, since Cu has a higher CTE than SiC. At higher soldering temperatures (˜300° C.), it becomes almost planar and may even flip over towards the “smiling face” such as that shown in FIG. 3B. In addition the isolator can be warped too due to the design and manufacturing process. Also the interposer can be warped too so that as a result both directions are possible.

FIGS. 4A and 4B show cross-sectional representations of semiconductor devices comprising additional copper blocks within the joint layer.

More specifically, FIG. 4A shows a semiconductor package 30 similar to the semiconductor packages shown and described in connection with FIGS. 1 and 2. The only difference is the particular configuration of the joint layer 34.

In the present case the joint layer 34 comprises additional copper blocks 34A. The copper blocks 34A are integrated in the joint layer 34. These copper blocks 34A are a special form of the solder material, in which so-called high-melting Cu metal cores are introduced in addition to the actual preform made of SnSb, in order to simplify diffusion soldering and the complete formation of the intermetallic phases in the Sn. Only are few copper blocks are shown in the cross-sectional representation, but in reality there can be many more. This concept can be realized with sheets, balls and wires.

More specifically, FIG. 4B shows a semiconductor package 40 similar to the semiconductor package 30 shown and described in connection with FIG. 4A. The only difference is the particular configuration of the joint layer 44. In this case the joint layer 44 comprises a layer stack of an intermediate Cu layer 44A sandwiched by Sn or SnSb layers 44B on top and on the bottom of the intermediate Cu layer 44A. The layers 44B are introduced in addition to the actual preform made of SnSb, in order to simplify diffusion soldering and the complete formation of the intermetallic phases in the Sn.

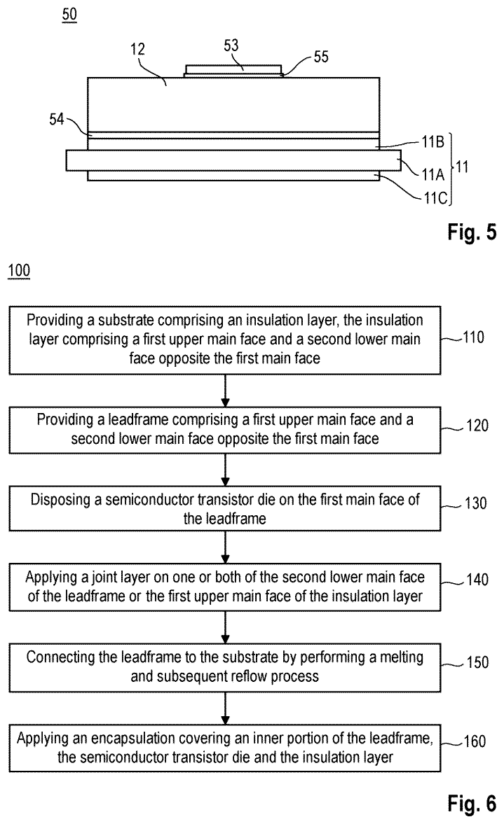

FIG. 5 shows a cross-sectional representation of a semiconductor device in order to focus on the attach layer.

More specifically, the semiconductor package 50 as shown in FIG. 5 comprises a substrate 11 comprising a DCB, AMB or IMS, a ceramic insulation layer 11A, the ceramic insulation layer 11A comprising a first upper main face and a second lower main face opposite to the first upper main face, furthermore a leadframe 12 comprising a first upper main face and a second lower main face opposite to the first main face, furthermore a semiconductor transistor die 53 arranged on the first main face of the leadframe 12, furthermore a joint layer 54 coupling the second lower main face of the leadframe 12 to the first upper main face of the ceramic insulation layer 11A, wherein the joint layer 54 comprises a melting point entirely or in parts of greater than 260° C. or greater than 300° C./400° C./500° C. or even greater, and an encapsulation covering an inner portion of the leadframe 12, the semiconductor transistor die 13, and the ceramic insulation layer 11 of the substrate 11. The semiconductor package 50 may also comprise an encapsulant (not shown) covering an inner portion of the leadframe 12, the semiconductor transistor die 53, and the ceramic insulation layer 11 of the substrate 11.

The semiconductor package 50 of FIG. 5 further comprises a die attach layer 55 connecting the semiconductor transistor die 53 to the upper surface of the leadframe 12.

With respect to the semiconductor die 53 and the joint layer 54 the same properties can be applied as were previously described in connection with the semiconductor die 13 and the joint layer 14 of the semiconductor package of FIG. 1.

The semiconductor die attach layer 55 connects the semiconductor transistor die 53 with the first main face of the leadframe 12 and maybe fabricated by a diffusion soldering process.

Furthermore the semiconductor die attach layer 55 may comprise a thickness thinner than the joint layer 54, in particular in a range from 1 μm to 100 μm.

Furthermore the semiconductor die attach layer 55 may comprise a melting point entirely or in parts of greater than 260° C. and may in particular comprise diffusion or sinter joint layer or layers.

FIG. 6 shows a flow diagram of an embodiment of the method according to the second aspect.

More specifically, the method 100 for fabricating a semiconductor package comprises providing a substrate comprising an insulation layer, the insulation layer comprising a first upper main face and a second lower main face opposite to the first upper main face (110), providing a leadframe comprising a first upper main face and a second lower main face opposite to the first main face (120), disposing a semiconductor transistor die on the first main face of the leadframe (130), applying a joint layer on one or both of the second lower main face of the leadframe or the first upper main face of the insulation layer, wherein the joint layer is formed by diffusion soldering or diffusion sintering from at least one source material with at least one first transition temperature, wherein after the forming, the joint layer has a second transition temperature higher than the first transition temperature (140), connecting the leadframe to the substrate by performing a melting and subsequent reflow process (150), and applying an encapsulation covering an inner portion of the leadframe, the semiconductor transistor die and the insulation layer (160).

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a substrate comprising an insulation layer, the insulation layer comprising a first upper main face and a second lower main face opposite to the first upper main face;
a leadframe comprising a first upper main face and a second lower main face opposite to the first main face;
a semiconductor transistor die arranged on the first main face of the leadframe;
a joint layer coupling the second lower main face of the leadframe to the first upper main face of the insulation layer, the joint layer having a melting point entirely or in parts of greater than 260° C.; and
an encapsulation covering an inner portion of the leadframe, the semiconductor transistor die, and the insulation layer.

2. The semiconductor package of claim 1, wherein the insulation layer comprises a ceramic insulation layer.

3. The semiconductor package of claim 1, wherein the joint layer is based on a metal.

4. The semiconductor package of claim 1, wherein the joint layer has a thickness in a range from 40 μm to 200 μm, or wherein the joint layer has a thickness in a range from 1 μm to 50 μm.

5. The semiconductor package of claim 1, wherein the joint layer comprises a material with a thermal conductivity of more than 15 W/mK.

6. The semiconductor package of claim 1, wherein the joint layer comprises one or more materials selected from the group consisting of a Pb free material, an SnSb material, an NiSn material, a CuSn material, a transient liquid phase soldering material, an Sn material, an Ag material, an Ag glue material, a hybrid sinter paste, and a Cu based sinter paste.

7. The semiconductor package of claim 1, wherein the insulation layer is a central layer of the substrate, wherein the substrate is one of a direct copper bond substrate, an active metal braze substrate, or an insulated metal substrate.

8. The semiconductor package of claim 7, wherein the substrate comprises a central insulating layer, a first upper metallic layer and a second lower metallic layer.

9. The semiconductor package of claim 7, wherein the first upper metallic layer has a thickness thinner than 2000 μm.

10. The semiconductor package of claim 1, wherein the substrate comprises a single ceramic insulating layer with a bottom surface being disposed to the outside.

11. The semiconductor package of claim 1, wherein the insulation layer comprises one or more materials selected from the group consisting of Al2O3, Si3N4, H—AlN, and AlN.

12. The semiconductor package of claim 1, further comprising:
a semiconductor die attach layer connecting the semiconductor transistor die with the first main face of the leadframe.

13. The semiconductor package of claim 12, wherein the semiconductor die attach layer has a thickness which is thinner than the joint layer.

14. The semiconductor package of claim 12, wherein the semiconductor die attach layer has a thickness in a range from 1 μm to 100 μm.

15. The semiconductor package of claim 12, wherein the semiconductor die attach layer has a melting point entirely or in parts of greater than 260° C.

16. The semiconductor package of claim 12, wherein the semiconductor die attach layer is fabricated by a diffusion soldering process.

17. A method for fabricating a semiconductor package, the method comprising:
providing a substrate comprising an insulation layer, the insulation layer comprising a first upper main face and a second lower main face opposite to the first upper main face;
providing a leadframe comprising a first upper main face and a second lower main face opposite to the first main face;
arranging a semiconductor transistor die on the first main face of the leadframe;
applying a joint layer on one or both of the second lower main face of the leadframe or the first upper main face of the insulation layer, the joint layer being formed by diffusion soldering or diffusion sintering from at least one source material with at least one first transition temperature, wherein after the forming, the joint layer has a second transition temperature higher than the first transition temperature;
connecting the leadframe to the substrate by performing a melting and subsequent reflow process; and
applying an encapsulation covering an inner portion of the leadframe, the semiconductor transistor die, and the insulation layer.
